(19) United States
(12) Patent Application Publication
(10) Pub. No.: US 2025/0234615 A1
(43) Pub. Date: Jul. 17, 2025

(54) SEMICONDUCTOR DEVICE AND METHOD OF MANUFACTURING THE SAME

(71) Applicant: STMICROELECTRONICS INTERNATIONAL N.V., Geneva (CH)

(72) Inventor: Daniele CAPELLI, Basiano (IT)

(21) Appl. No.: 18/411,451

(22) Filed: Jan. 12, 2024

(51) Int. Cl. H01L 29/40; H01L 23/31; H01L 29/20; H01L 29/66; H01L 29/778

(52) U.S. Cl. CPC H10D 64/112; H01L 23/3171; H10D 30/015; H10D 30/475; H10D 62/8503; H10D 64/01

(57) ABSTRACT

In accordance with various embodiments of the present disclosure, a semiconductor device is provided. In some embodiments, the semiconductor device comprises a substrate made of a semiconductor material, a gate structure placed on the substrate, a passivation layer placed on the substrate and on a portion of the gate structure, a sealing oxide layer placed on the passivation layer, a first field plate placed on a portion of the sealing oxide layer, a dielectric layer placed on the first field plate and on the sealing oxide layer, a second field plate placed on a portion of the layer, and a source contact metallization and a drain contact metallization. The sealing oxide layer is thicker than the passivation layer.

### FIELD OF THE INVENTION

Example embodiments of the present disclosure relate generally to structures for semiconductor devices and, more particularly, to structures for gallium nitride (GaN) high electron mobility transistor (HEMT) devices.

### BACKGROUND

Gallium nitride (GaN) high electron mobility transistors (HEMTs) are increasingly used for power electronics, especially for some high-power applications. Applicant has identified many technical challenges and difficulties associated with manufacturing semiconductor devices, such as GaN HEMTs. Through applied effort, ingenuity, and innovation, Applicant has solved problems related to manufacturing semiconductor devices, such as GaN HEMTs, by developing solutions embodied in the present disclosure, which are described in detail below.

### BRIEF SUMMARY

Various embodiments described herein related to semiconductor devices and methods of manufacturing semiconductor devices.

In accordance with various embodiments of the present disclosure, a semiconductor device is provided. In some embodiments, the semiconductor device comprises a substrate made of a semiconductor material, a gate structure placed on the substrate, a passivation layer placed on the substrate and on a portion of the gate structure, a sealing oxide layer placed on the passivation layer, a first field plate placed on a portion of the sealing oxide layer, a dielectric layer placed on the first field plate and on the sealing oxide layer, a second field plate placed on a portion of the layer, and a source contact metallization and a drain contact metallization. The sealing oxide layer is thicker than the passivation layer.

In some embodiments, the dielectric layer comprises a nitride layer or an oxide layer.

In some embodiments, the source contact metallization and the drain contact metallization formed on corresponding portions of the substrate in corresponding voids in the passivation layer, the sealing oxide layer, and the dielectric layer.

In some embodiments, the dielectric layer comprises a first dielectric sub-layer and a second dielectric sub-layer.

In some embodiments, the first dielectric sub-layer is partially overlapped by the source and drain contact metallizations.

In some embodiments, the second dielectric sub-layer overlaps the source and drain contact metallizations.

In some embodiments, the dielectric layer is a first dielectric layer and the semiconductor device further comprises a second dielectric layer placed on the second field plate and on a portion of the first dielectric layer.

In some embodiments, the semiconductor device further comprises a gate contact metallization placed on the gate structure in a void in the second dielectric layer, the first dielectric layer, the sealing oxide layer, and the passivation layer.

In some embodiments, the gate structure is made of gallium nitride (GaN) and the semiconductor device comprises a GaN high electron mobility transistor.

In some embodiments, the second field plate partially contacts the first field plate through a further void in the dielectric layer.

In accordance with various embodiments of the present disclosure, a method for manufacturing a semiconductor device is provided. In some embodiments, the method comprises forming a gate structure on a substrate made of a semiconductor material, forming a passivation layer on the substrate and on a portion of the gate structure, forming a sealing oxide layer on the passivation layer, wherein the sealing oxide layer is thicker than the passivation layer, forming a first field plate on a portion of the sealing oxide layer, forming a dielectric layer on the first field plate and on the sealing oxide layer, forming a second field plate on a portion of the dielectric layer, and forming a source contact metallization and a drain contact metallization.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIGS. 1-13 are schematic cross-sectional views illustrating steps of an example method of manufacturing a semiconductor device, in accordance with some embodiments of the present disclosure;

FIG. 14 is a schematic cross-sectional view of an example semiconductor device, in accordance with some embodiments of the present disclosure; and

FIG. 15 is a schematic cross-sectional view illustrating a step of an example method of manufacturing a semiconductor device, in accordance with some alternative embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

GaN HEMTs typically comprise one or more field plates. A field plate is a metallic electrode (which may be made of Titanium Nitride (TiN), Aluminum Copper (AlCu), or any other suitable material) biased to a certain voltage, used to modify and control the voltage and electric field peak along the conductive channel of the transistor. The voltage between the conductive channel and the field plate may be sustained by a capacitor-like structure with a dielectric medium (typically Silicon Oxide or Silicon Nitride).

Some problems can arise during the formation (definition) of the field plate that can cause some residues (which may be termed stringers) to remain in some unwanted areas, for example at the vertical or concave walls of the ohmic (drain & source) metallizations. These residues could cause unwanted electrical effects and/or a loss of electrical performance of the HEMT. In other cases, when the Silicon Nitride (SiN) sealing layer is etched around the gate to create an opening that enables formation of the field plate, the mask to create the SiN opening may not be precisely located, thus removing too much SiN and/or too much Silicon Oxide (SiO) (in the layer below the SiN) and forming holes. Unwanted materials (e.g., TiN) may fill the holes, thus causing unwanted electrical effects and/or a loss of electrical performance of the HEMT.

Various embodiments of the present disclosure overcome the above technical challenges and difficulties and provide various technical improvements and advantages based on, for example, but not limited to, semiconductor devices and methods of manufacturing semiconductor devices as described herein.

Various embodiments of the present disclosure provide semiconductor devices and methods of manufacturing semiconductor devices in which a passivation layer and then a gate sealing layer are applied prior to creation of a first of two separate field plates. Various embodiments of the present disclosure provide semiconductor devices and methods of manufacturing semiconductor devices in which creation of a first of two separate field plates is performed separately from gate metallization. Various embodiments of the present disclosure provide semiconductor devices and methods of manufacturing semiconductor devices in which the sealing nitride layer is not etched for field plate creation. Various embodiments of the present disclosure provide semiconductor devices and methods of manufacturing semiconductor devices in which a three-step gate contact etch is performed.

FIGS. 1-13 are schematic cross-sectional views illustrating steps of an example method of manufacturing a semiconductor device, such as a GaN HEMT, in accordance with some embodiments of the present disclosure. Referring now to FIG. 1, a gate structure 104 is formed on a substrate 102. The substrate 102 may comprise, for example, Silicon Carbide (SiC) or Silicon (Si), which are commonly used for the substrate of a GaN HEMT. Alternatively, the substrate may comprise a stack of Aluminum Gallium Nitride (AlGaN) and GaN. The gate structure 104 may comprise, for example, p-Type Gallium Nitride (p-GaN) with Magnesium (Mg) doping. A passivation layer 106 is formed on top of the substrate 102 and the gate structure 104. The passivation layer 106 may comprise, for example, materials such as Silicon Dioxide (SiO2), Aluminum Oxide (e.g., Alumina, Al2O3), Aluminum Nitride (AlN), or Gallium Oxide (Ga2O3) (or other similar non-stoichiometric oxides). A sealing dielectric layer (which may also be termed a gate sealing dielectric layer) is deposited over the passivation layer 106. Typically, the sealing dielectric layer is made of an oxide material (such as in the following named sealing oxide layer 108). Alternatively, the sealing dielectric layer can be made of a nitride material.

The sealing oxide layer 108 may comprise, for example, SiO2. In various embodiments, having the passivation layer contacting the gate structure and having the gate sealing oxide layer over the passivation layer enables a thinner gate sealing oxide layer as compared to other approaches that have been used. In various embodiments, having a thinner gate sealing oxide layer as compared to other approaches that have been used may provide a better reduction of the peaks of the electrical field and control of the hot carrier, with consequent beneficial effects on electrical properties of the device. In various embodiments, the sealing oxide layer 108 is thicker than the passivation layer 106. For example, in some embodiments the sealing oxide layer is about eight to twelve times thicker than the passivation layer (the passivation layer is typically about 5-10 nanometers thick, while the sealing oxide layer is typically about 30-120 nm, and preferably about 40-100 nm, thick). For example, in some embodiments the sealing oxide layer is about ten times thicker than the passivation layer. In various embodiments, the sealing oxide layer should match a target value since the sealing oxide layer is used as a dielectric for the field plate “capacitor like” structure. In various embodiments, too low thickness of the sealing oxide layer results in poor control of the residual sealing layer after patterning of a first field plate, while too high thickness of the sealing oxide layer results in too low capacitance value and coupling to channel of the first field plate.

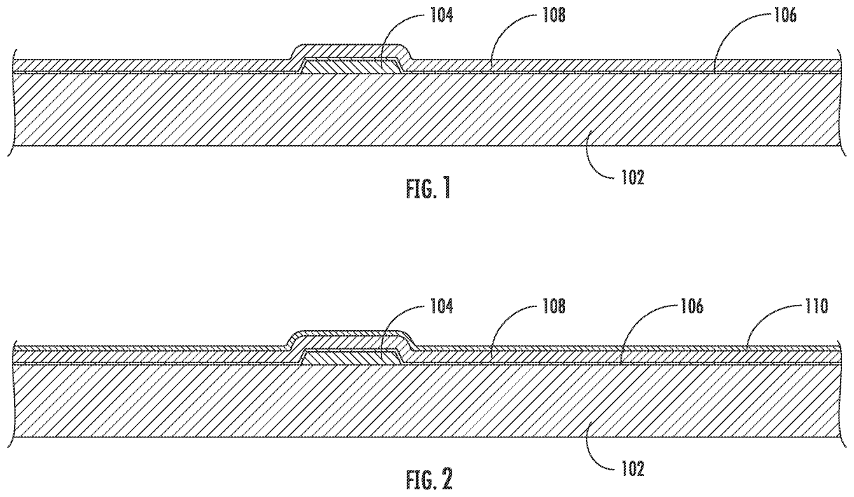

Referring now to FIG. 2, a metallic layer 110 is deposited over the sealing oxide layer 108. The metallic layer 110 may comprise, for example, TiN. In various embodiments, better control of the thickness of the sealing oxide layer may be obtained as the only source of variability of the thickness of the sealing oxide layer is the sealing oxide deposition itself.

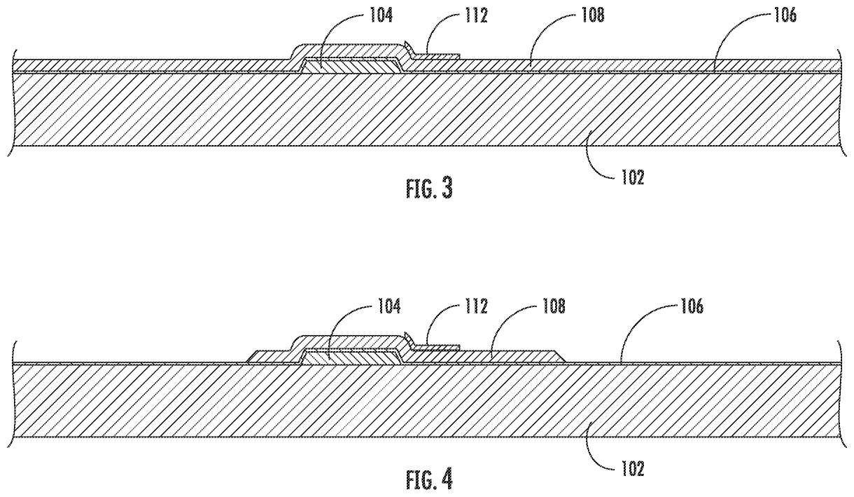

Referring now to FIG. 3, the metallic layer is patterned and etched to create a first field plate 112 by removing all of the metallic layer 110 except for the portion that forms the first field plate 112. Referring now to FIG. 4, the sealing oxide layer 108 is patterned and etched to remove unneeded material on opposing sides of the gate structure 104. In various embodiments, the sealing oxide layer 108 is protected by the first field plate 112 and therefore better overall electrical behavior of the HEMT may be achieved.

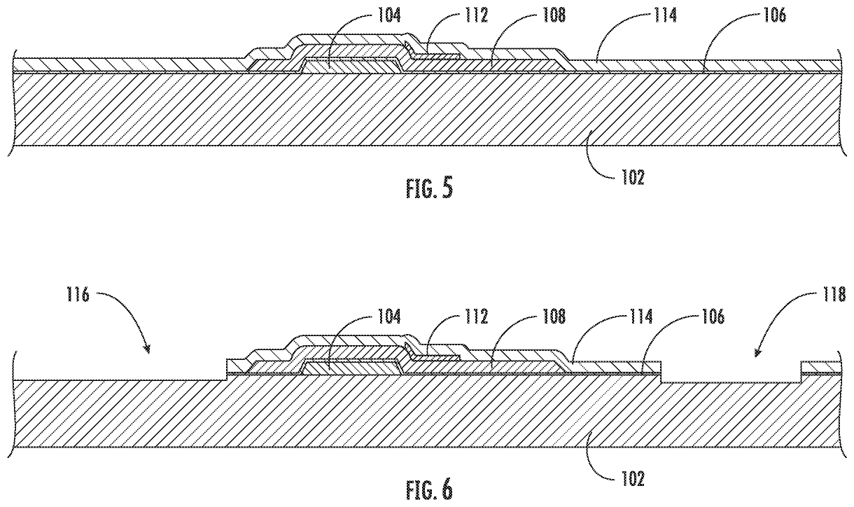

Referring now to FIG. 5, a dielectric layer comprising a first dielectric sub-layer such as a contact nitride layer 114 (which, in various alternative embodiments, may be an oxide layer) is deposited over the first field plate 112, portions of the sealing oxide layer 108, and portions of the passivation layer 106. The contact nitride layer 114 may comprise, for example, Silicon Nitride (SiN or Si3N4) or other dielectric such as Silicon Oxide (SiO2). This layer is termed the contact nitride layer because this layer is etched to form the source and drain contacts. Referring now to FIG. 6, the contact nitride layer 114 is patterned and etched to remove corresponding portions of the contact nitride layer 114 and the passivation layer 106 to create a source void 116 to allow for the source contact to be deposited on the substrate 102 and a drain void 118 to allow for the drain contact to be deposited on the substrate 102. (Alternatively, a drain contact could be deposited in void 116 and a source contact could be deposited in void 118.) In various alternative embodiments, a second passivation layer (not illustrated) (which may, for example, be made of the same or different material as the passivation layer 106) could be present. In various embodiments, the second passivation layer can be deposited after definition of the gate sealing oxide layer 108 and would be conformal to the underlying structure. In various embodiments, the second passivation layer can be etched together with the dielectric layer 114 when defining the voids for the contact metallizations. In various embodiments, the second passivation layer would remain under the dielectric layer 114 after definition of the above said voids.

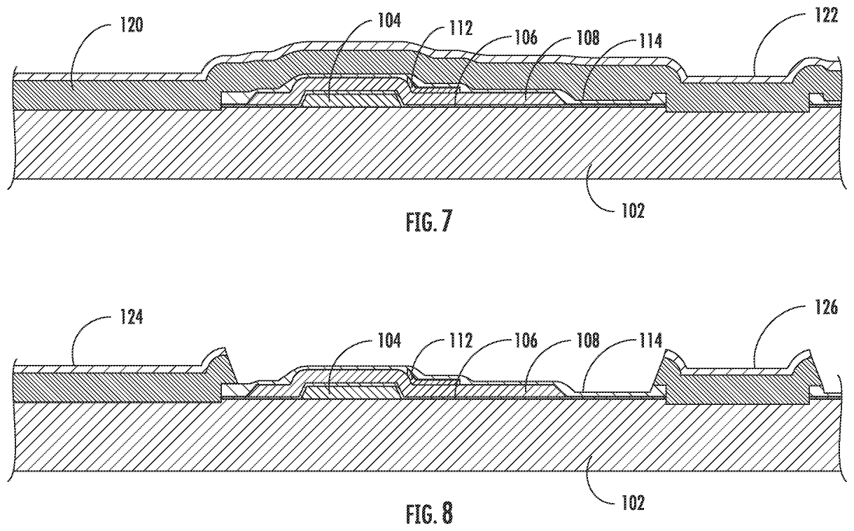

Referring now to FIG. 7, a contact layer 120 and another metallic layer 122 have been deposited. In various embodiments, the contact layer 120 and the metallic layer 122 are a metallic stack deposited in a single deposition step, and may comprise, for example, Titanium (Ti), Titanium Nitride (TiN), Aluminum Copper (AlCu), and/or other materials used in conventional aluminum interconnects. Referring now to FIG. 8, the contact layer 120 and the metallic layer 122 have been patterned and etched to expose the area around the gate structure 104 and form the source contact 124 and the drain contact 126. (Alternatively, contact 124 could be a drain contact and contact 126 could be a source contact.)

Referring now to FIG. 9, the dielectric layer further comprises a second dielectric sub-layer such as a sealing nitride layer 128, which is deposited on the source/drain metallizations 124 and 126, and the first dielectric sub-layer. The sealing nitride layer 128 may comprise, for example, SiN. This layer protects the metallic layer on top of the source contact 124 and the drain contact 126. In various embodiments, the sealing nitride layer is not directly etched to enable field plate formation, unlike other approaches that have been used. As such, the necessity of accurately placing the mask, and the implied and related issues of controlling the photolithography process, to create a SiN opening is avoided. In alternative embodiments (not shown), the dielectric layer consists of the first dielectric sub-layer (i.e., does not comprise the second dielectric sub-layer).

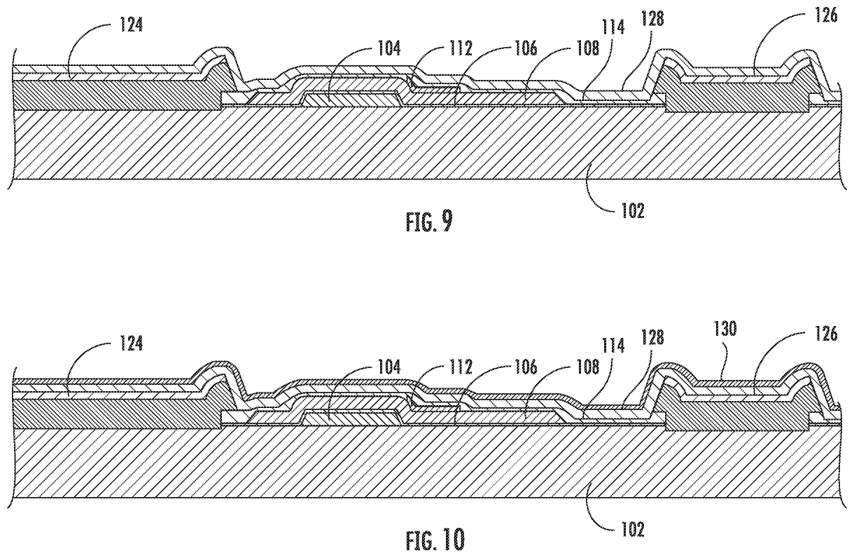

Referring now to FIG. 10, a metallic layer 130 is deposited over the sealing nitride layer 128. The metallic layer 130 may comprise, for example, TiN. In various embodiments, the above-described problem of residue remaining at the vertical or concave walls of the ohmic (drain & source) metallizations may be reduced or avoided by applying the metallic layer 130 with low thickness (for example, about 20-60 nanometers) and/or applying with a process (such as physical vapor deposition) that provides low step coverage. Referring now to FIG. 11, the metallic layer is patterned and etched to create a second field plate 132 by removing all of the metallic layer 130 except for the portion that forms the second field plate 132. In various embodiments, the above-described problem of residue remaining at the vertical or concave walls of the ohmic (drain & source) metallizations may be further reduced or avoided by using an isotropic etching process to remove the unneeded portions of the metallic layer 130. In various embodiments, it may be possible to bias the two field plates at two different voltages. In various embodiments, the thickness of the first and second field plates ranges from 20 nm to 100 nm, which in some cases, are thinner than in the case of a single field plate. In the illustrated embodiment, the first and second field plates do not overlap. In various alternative embodiments, the first and second field plates may partially overlap. In various embodiments, it is possible to leave further portions of the metallic materials from which the first and second field plates originate. These further portions can be used as a passive component, for example can be used as electrodes for a MIM (metal-insulator-metal) capacitor structure (e.g., the dielectric layer acting as the insulation layer between the two metallic plates). In the case of a MIM capacitor, the further portions are overlapped to each other.

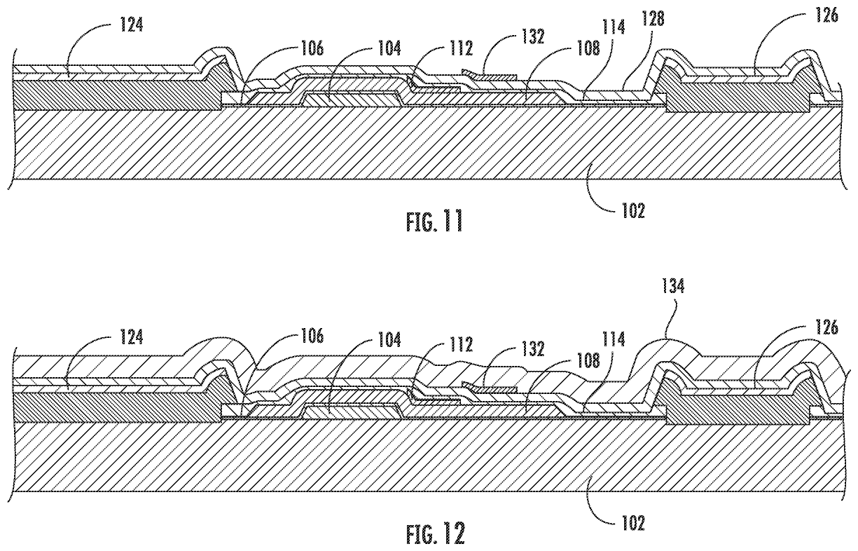

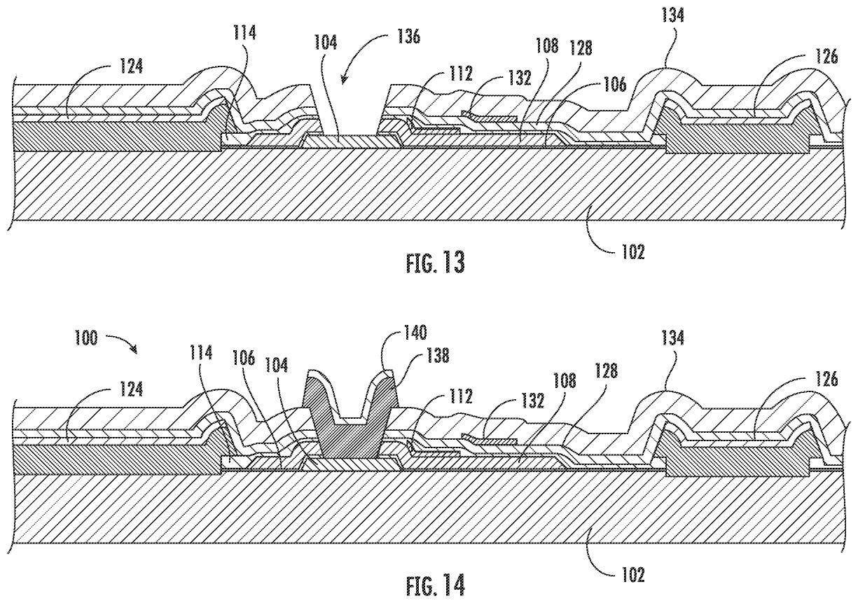

Referring now to FIG. 12, a gate contact dielectric layer (typically made of oxide material, and therefore called gate contact dielectric oxide layer 134 below) is deposited over the second field plate 132 and portions of the sealing nitride layer 128. The gate contact dielectric oxide layer 134 may comprise, for example, SiO. Referring now to FIG. 13, a three-step etching process is performed to remove the gate contact dielectric oxide layer 134, the sealing nitride layer 128, the sealing oxide layer 108, and the passivation layer 106 over the gate structure 104, creating a gate void 136. In various embodiments, the selectivity of etching an oxide over SiN and etching SiN over an oxide enables better control of the final etch step.

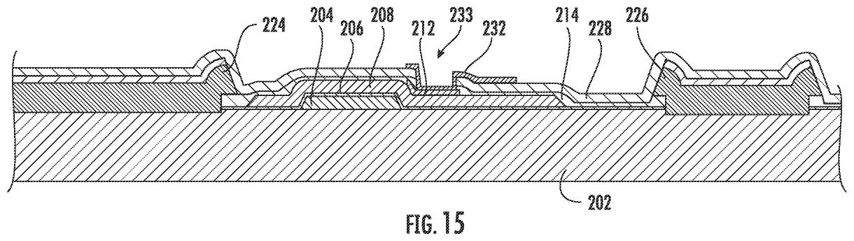

Subsequently, a gate contact is formed on top of the gate structure 104 to form the completed device shown in FIG. 14. FIG. 14 illustrates a GaN semiconductor device 100 of embodiments of the present disclosure. In the device 100 of FIG. 14, a contact layer 138 and another metallic layer 140 have been deposited and then patterned and etched to remove unneeded material to form the gate contact 142. In various embodiments, the contact layer 138 and the metallic layer 140 are a metallic stack deposited in a single deposition step, and may comprise, for example, Titanium (Ti), Titanium Nitride (TiN), Aluminum Copper (AlCu), and/or other materials used in conventional aluminum interconnects. The process integration of embodiments of the present disclosure advantageously allows to form the gate contact metallization 142 (i.e., the contact layer 138 and the metallic layer 140) after the first field plate is formed, thereby providing a dedicated process with improved precision and/or accuracy.

FIG. 15 is a schematic cross-sectional view illustrating a step of an example method of manufacturing a semiconductor device, in accordance with some alternative embodiments of the present disclosure. Similar to the steps described in relation to FIGS. 1-9 above, FIG. 15 shows the following formed on a substrate 202: a gate structure 204, a passivation layer 206, a sealing oxide layer 208, a first field plate 212, contact nitride layer 214, a source contact 224, a drain contact 226, and sealing nitride layer 228. After the sealing nitride layer 228 is deposited, the sealing nitride layer 228 is patterned and etched to remove portions of the sealing nitride layer 228 to create a second field plate void 233. A metallic layer (not illustrated) is deposited and then patterned and etched to create a second field plate 232 by removing all of the metallic layer except for the portion that forms the second field plate 232. In the alternative embodiment of FIG. 15, the second field plate 232 has a (exemplarily center) portion that contacts the first field plate 212. By having the first field plate and the second field plate directly connected as shown in FIG. 15, it is possible to bias the first and second field plate at the same potential, avoiding the formation of one or more vias can be avoided in applications in which are always.

The layers of the semiconductor device described herein (e.g., the passivation layer, the sealing oxide layer, the metallic layers, the contact nitride layers, the gate contact dielectric oxide layer) may be formed using any suitable technique for forming layers on a semiconductor device, such as, but not limited to, physical vapor deposition or chemical vapor deposition.

Various embodiments of the invention provide a semiconductor device and method of manufacturing a semiconductor device involving a 100-volt integrated circuit. Various alternative embodiments of the invention provide a semiconductor device and method of manufacturing a semiconductor device involving higher voltage ratings.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to structures for GaN HEMT devices, however, one skilled in the art may recognize that such principles may be applied to other semiconductor devices. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims may cover other forms of semiconductor devices, such as, in some applications, power LDMOS (laterally-diffused metal-oxide semiconductor) devices in BCD (Bipolar-CMOS-DMOS) platforms in which a double field plate is used.

Within the appended claims, unless the specific term “means for” or “step for” is used within a given claim, it is not intended that the claim be interpreted under 35 U.S.C. 112, paragraph 6.

What is claimed is:

1. A semiconductor device comprising:
a substrate made of a semiconductor material;
a gate structure placed on the substrate;
a passivation layer placed on the substrate and on a portion of the gate structure;
a sealing dielectric layer placed on the passivation layer, wherein the sealing dielectric layer is thicker than the passivation layer;
a first field plate placed on a portion of the sealing dielectric layer;
a dielectric layer placed on the first field plate and on the sealing dielectric layer;
a second field plate placed on a portion of the dielectric layer; and
a source contact metallization and a drain contact metallization.

2. The semiconductor device of claim 1, wherein the sealing dielectric layer and the dielectric layer are made of a nitride or an oxide material.

3. The semiconductor device of claim 1, wherein the source contact metallization and the drain contact metallization formed on corresponding portions of the substrate in corresponding voids in the passivation layer, the sealing dielectric layer, and the dielectric layer.

4. The semiconductor device of claim 1, wherein the dielectric layer comprises a first dielectric sub-layer and a second dielectric sub-layer.

5. The semiconductor device of claim 4, wherein the first dielectric sub-layer is partially overlapped by the source and drain contact metallizations.

6. The semiconductor device of claim 4, wherein the second dielectric sub-layer overlaps the source and drain contact metallizations.

7. The semiconductor device of claim 1, further comprising a gate contact dielectric layer placed on the second field plate and on a portion of the dielectric layer.

8. The semiconductor device of claim 7, further comprising a gate contact metallization placed on the gate structure in a void in the gate contact dielectric layer, the dielectric layer, the sealing dielectric layer, and the passivation layer.

9. The semiconductor device of claim 1, wherein the gate structure is made of gallium nitride (GaN); and wherein the semiconductor device comprises a GaN high electron mobility transistor.

10. The semiconductor device of claim 1, wherein the second field plate partially contacts the first field plate through a further void in the dielectric layer.

11. A method of manufacturing a semiconductor device, the method comprising:
forming a gate structure on a substrate made of a semiconductor material;
forming a passivation layer on the substrate and on a portion of the gate structure;
forming a sealing dielectric layer on the passivation layer, wherein the sealing dielectric layer is thicker than the passivation layer;
forming a first field plate on a portion of the sealing dielectric layer;
forming a dielectric layer on the first field plate and on the sealing dielectric layer;
forming a second field plate on a portion of the dielectric layer; and
forming a source contact metallization and a drain contact metallization.

12. The method of claim 11, wherein the sealing dielectric layer and the dielectric layer are made of a nitride or an oxide material.

13. The method of claim 11, wherein the source contact metallization and the drain contact metallization are formed on corresponding portions of the substrate in corresponding voids in the passivation layer, the sealing dielectric layer, and the dielectric layer.

14. The method of claim 11, wherein the dielectric layer comprises a first dielectric sub-layer and a second dielectric sub-layer.

15. The method of claim 14, wherein the first dielectric sub-layer is partially overlapped by the source and drain contact metallizations.

16. The method of claim 14, wherein the second dielectric sub-layer overlaps the source and drain contact metallizations.

17. The method of claim 11, further comprising a gate contact dielectric layer placed on the second field plate and on a portion of the dielectric layer.

18. The method of claim 17, further comprising:
forming a gate contact metallization on the gate structure in a void in the gate contact dielectric layer, the dielectric layer, the sealing dielectric layer, and the passivation layer.

19. The method of claim 18, wherein the gate contact metallization is formed after the first field plate is formed.

20. The method of claim 11, wherein the second field plate partially contacts the first field plate through a further void in the dielectric layer.
